(19) United States
(12) Patent Application Publication
(10) Pub. No.: US 2014/0001494 A1
(43) Pub. Date: Jan. 2, 2014

(54) LIGHT EMITTING DIODE

(71) Applicant: ADVANCED OPTOELECTRONIC TECHNOLOGY, INC., Hsinchu Hsien (TW)

(72) Inventors: CHIA-HUI SHEN, Hukou (TW); TZU-CHIEN HUNG, Hukou (TW); JIAN-SHIHN TSANG, Hukou (TW)

(73) Assignee: ADVANCED OPTOELECTRONIC TECHNOLOGY, INC., Hsinchu Hsien (TW)

(21) Appl. No.: 14/014,428

(22) Filed: Aug. 30, 2013

Related U.S. Application Data
(63) Continuation-in-part of application No. 13/041,429, filed on Mar. 6, 2011.

(30) Foreign Application Priority Data
Aug. 5, 2010 (CN) 2010102458035

(51) Int. Cl. H01L 31/12

(52) U.S. Cl. CPC H01L 31/12
USPC 257/84

(57) ABSTRACT

A light emitting diode includes a first illumination region, a second illumination region, and the third illumination, wherein a first fluorescent conversion layer and a second fluorescent conversion layer cover the first illumination region and the second illumination region, respectively. The fluorescent conversion layers can convert lights from the illumination regions to other lights with different wavelengths whereby the light emitting diode generates light with multiple wavelengths.

### CROSS-REFERENCE TO RELATED APPLICATIONS

This application is a continuation-in-part of U.S. Ser. No. 13/041,429 filed Mar. 6, 2011, entitled “Light Emitting Diode”, assigned to the same assignee as the present disclosure and claiming China priority of CN 201010245803.5 filed on Aug. 5, 2010; both applications are hereby incorporated by reference in their entirety.

### BACKGROUND

1. Technical Field

The disclosure relates generally to light emitting diodes, and more particularly to a light emitting diode with multiple wavelengths.

2. Description of the Related Art

Many illumination products use light emitting diode or laser diodes as a light source, such as environmental lighting or display backlighting, thanks to optimum lifetime, low energy consumption and heat generation, and compact profile.

White light is often generated by blue chips packaged with yellow phosphor, or multiple chip packages, such as those combining red, green, and blue chips. U.S. Pat. No. 7,635,870 discloses a multiple chip package like that described. US Patent Application Publication No. 2009/0140271 A1 disclosed that a wavelength converting material 47 is, for example but not limited to, a fluorescent converting layer. The wavelength converting material 47 may be used to change the color the light emitted from the light emitting unit 4b for increasing the applications of the of the light emitting unit 4b. The wavelength converting material 47 may be a wavelength converting material layer or a wavelength converting material tape having the wavelength converting material, e.g. a phosphor tape. U.S. Pat. No. 6,538,191 B1 disclosed that fluorescent layer 18 contains a fluorescent dye which affects a “Stokes shift” on light 12. As is known to those skilled in the art, a Stokes shift is the displacement of spectal lines or bands of luminescent radiation toward longer wavelengths than those of the absorption lines or bands. These fluorescent materials are well known to those skilled in the art and are presented in a table entitled “Flurochrome Data Tables: Excitation/Emission Wavelengths Listed by Flurochrome,” which was prepared by Michael W. Davidson, Mortimer Abramovitz, Olympus America Inc., and The Florida State University.

Although the blue chip with yellow phosphor package can generate white light, the color rendering index (CRI) is insufficient, especially in the red spectrum range, being less than other ranges, such as yellow and green. Additionally, while the multi-chip package has a higher CRI, the different color chips exhibit different decay times, to result in the yield of the package decreasing. Another issue in the multi-chip package is the distance between the chips for wire bonding, resulting in excessive total volume of the package. Therefore, it is desired to provide an LED package which can overcome the described limitations.

### BRIEF DESCRIPTION OF THE DRAWINGS

FIG. 1 is a cross section of a light emitting diode in accordance with a first embodiment of the disclosure.

FIG. 2A to FIG. 2E shows different circuit structures of the light emitting diode in accordance with a first embodiment of the disclosure.

FIG. 3 is a cross section of a light emitting diode in accordance with a second embodiment of the disclosure.

FIG. 4 is a cross section of a light emitting diode in accordance with a third embodiment of the disclosure.

FIG. 5 is a cross section of a light emitting diode in accordance with a fourth embodiment of the disclosure.

FIG. 6 is a cross section of a light emitting diode in accordance with a fifth embodiment of the disclosure.

### DETAILED DESCRIPTION

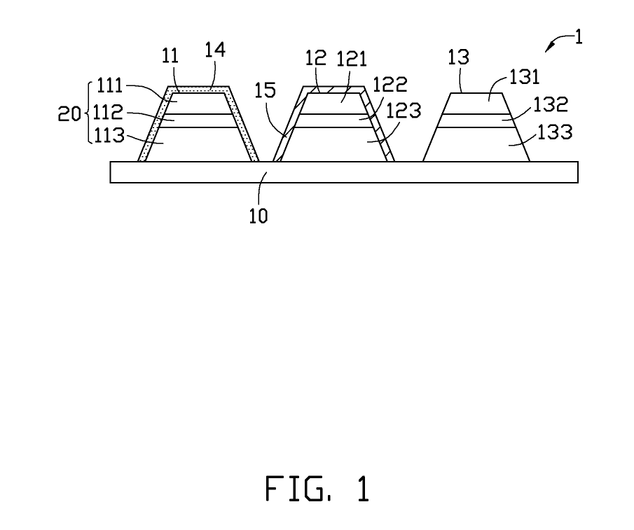

Referring to FIG. 1, a light emitting diode 1 in accordance with a first embodiment of the disclosure includes a substrate 10, an illumination structure 20, a first fluorescent conversion layer 14, and a second fluorescent conversion layer 15. In the first embodiment, the substrate 10 is a semiconductor substrate of aluminum oxide, silicon carbide, lithium aluminate, lithium gallate, silicon, gallium nitride, zinc oxide, aluminum zinc oxide, gallium arsenide, gallium phosphide, gallium antimonide, indium phosphide, indium arsenide, zinc selenide or metal.

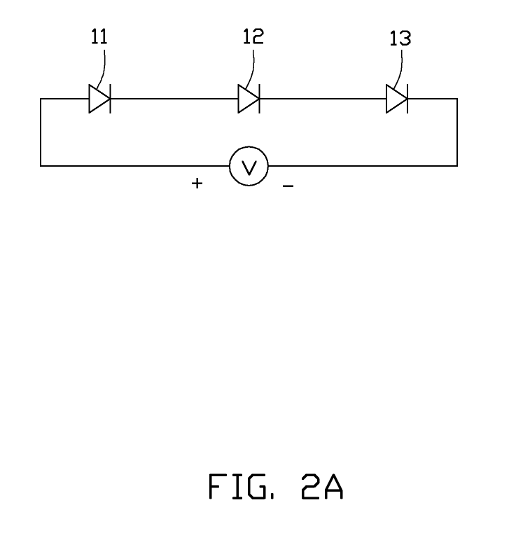

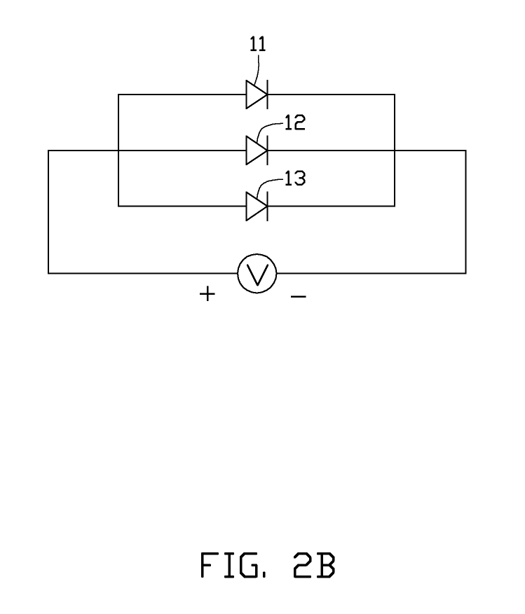

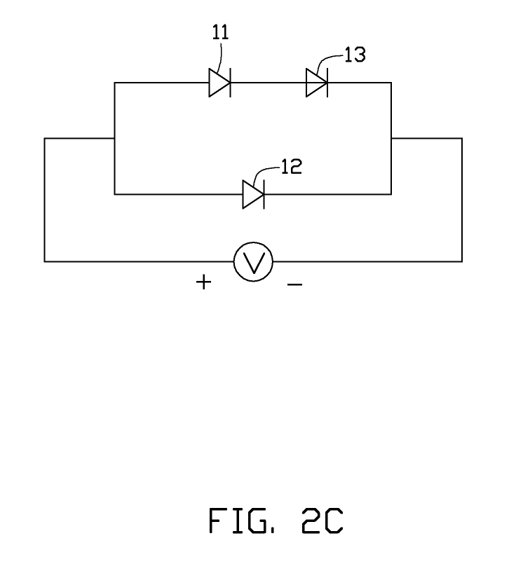

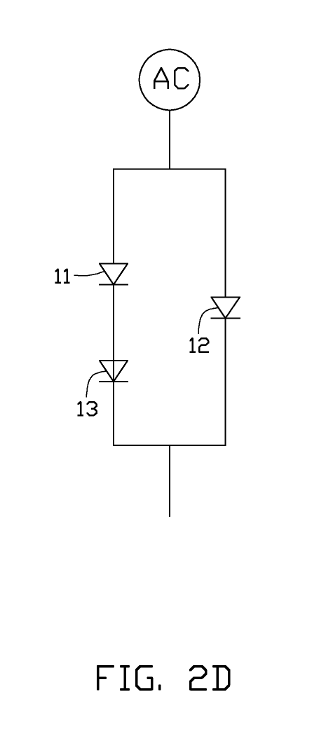

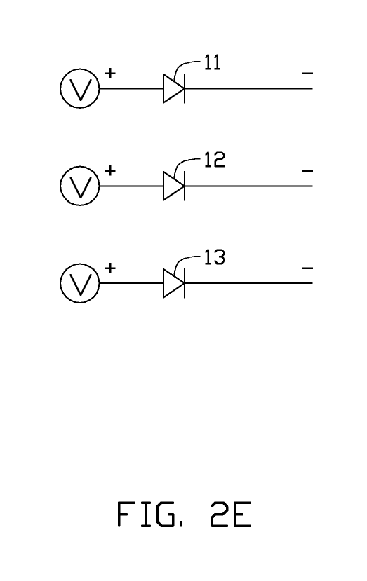

The illumination structure 20 is disposed on the substrate 10 and includes a first illumination region 11, a second illumination region 12, and a third illumination region 13. In the first embodiment, a space between the first illumination region 11 and the second illumination region 12 or between the second illumination region 12 and the third illumination region 13 is less than 50 μm. The first illumination region 11, the second illumination region 12, and the third illumination region 13 have p-type semiconductor layers 111, 121, 131, n-type semiconductor layers 113,123,133, and illumination layers 112, 122, 132, wherein the illumination layers 112, 122, 132 are between the p-type semiconductor layers 111, 121, 131 and the n-type semiconductor layers 113,123,133 respectively. The illumination structure 20 can be Group III-V or Group II-VI compound semiconductor, such as gallium nitride, indium gallium nitride, aluminum gallium nitride, aluminum indium gallium nitride, zinc oxide, or zinc sulfide, formed by metal organic chemical vapor deposition (MOCVD) or molecular beam epitaxy (MBE). The p-type semiconductor layers 111, 121, 131 are doped by Group II, such as magnesium (Mg). The n-type semiconductor layers 113, 123, 133 are doped by Group IV, such as silicon (Si). The illumination layers 112, 122, 132 can be single quantum well or multiple quantum well, and emit the same wavelength, such as ultraviolet, blue light, or green light. Furthermore, the n-type semiconductor layers 113, 123, 133 of the illumination structure 20 are physically separated from each other. In the different electrical connections as shown in FIG. 2A to FIG. 2E, the first illumination region 11, the second illumination region 12, and the third illumination region 13 can be electrically connected together in series (FIG. 2A) to a DC (direct current) power source, in parallel to a DC power source (FIG. 2B), in hybrid (i.e., series-parallel) to a DC power source (FIG. 2C), or to an AC (alternating current) power source (FIG. 2D). Alternatively, the first, second and third illumination regions 11, 12, 13 are independently connected to different DC power sources (FIG. 2E).

In the first embodiment, the n-type semiconductor layers 113, 123, 133 and the substrate 10 can have an undoped semiconductor layer (not shown in FIG. 1) therebetween to minimize the differences of the lattice constant and the thermal expansion coefficient between the illumination structure 20 and the substrate 10, thereby avoiding dislocation.

Referring to FIG. 1 again, the first fluorescent conversion layer 14 covers the surface of the first illumination region 11 and can convert light emitted from the first illumination region 11 to another light having a different wavelength. For example, the first fluorescent conversion layer 14 is made of nitride compounds; the first illumination region 11 can generate blue light, and the first fluorescent conversion layer 14 can convert the blue light to red light, resulting in that light from the first fluorescent conversion layer 14 on the first illumination region 11 appears to be red. Similarly, the second fluorescent conversion layer 15 covers the surface of the second illumination region 12 and can convert light from the second illumination region 12 to another light having a different wavelength. For example, the second fluorescent conversion layer 15 is made of nitride oxide compounds; the second illumination region 12 can generate blue light, and the second fluorescent conversion layer 15 can convert the blue light to green light. Therefore, the second fluorescent conversion layer 15 on the second illumination region 12 can radiate green light. The light emitting diode 1 thereby is capable of mixing different colored lights to obtain a light with a desired color.

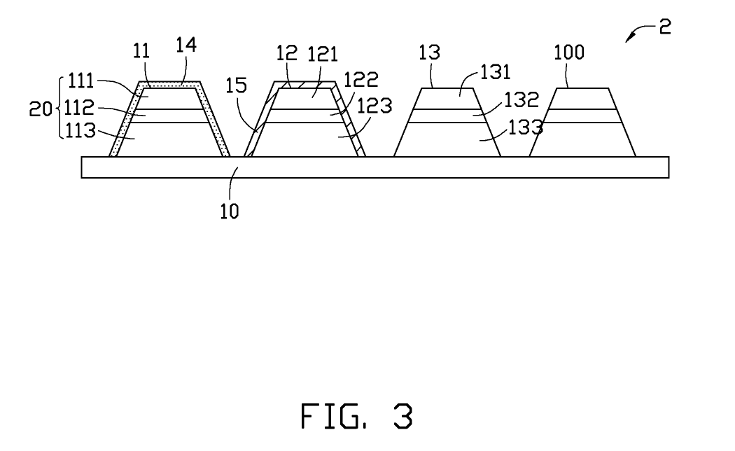

Referring to FIG. 3, a light emitting diode 2 in accordance with a second embodiment of the disclosure has the similar structure as the first embodiment. The difference therebetween is in that the light emitting diode 2 further comprises a photo detector 100 on the substrate 10. The photo detector 100 detects the light intensity from the light emitting diode 2, and provides a feedback system to control the input current to the light emitting diode 2, so that the light emitting diode 2 can obtain the desired color rendering index (CRI) from the mixed different colored lights. For example, when the photo detector detects that the intensity of light from the second illumination region 12 is insufficient, the feedback system would increase the input current to the second illumination region 12 so as to obtain the desired color rendering index (CRI) of the mixed light. Therefore, the photo detector 100 allows adjustment of the input currents to obtain a desired color rendering index (CRI) of the light mixed.

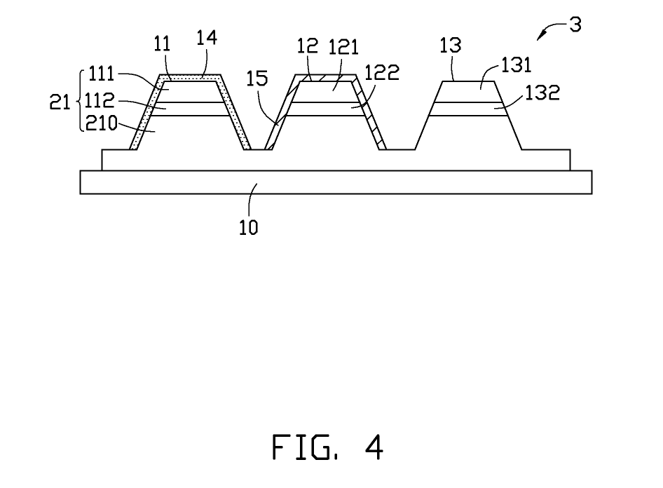

Referring to FIG. 4, a light emitting diode 3 in accordance with a third embodiment of the disclosure differs from the first embodiment in that the first illumination region 11, the second illumination region 12, and the third illumination region 13 are integrally formed as a single piece of an n-type semiconductor layer. The first illumination region 11 has a part of the n-type semiconductor layer 210, an illumination layer 112, and a p-type semiconductor layer 111, wherein the illumination layer 112 is on the part of the n-type semiconductor layer 210 and the p-type semiconductor layer 111 is on the illumination layer 112. The second illumination region 12 has a part of the n-type semiconductor layer 210, an illumination layer 122, and a p-type semiconductor layer 121, wherein the illumination layer 122 is on the part of the n-type semiconductor layer 210 and the p-type semiconductor layer 121 is on the illumination layer 122. The third illumination region 13 has a part of the n-type semiconductor layer 210, an illumination layer 132, and a p-type semiconductor layer 131, wherein the illumination layer 132 is on the part of the n-type semiconductor layer 210 and the p-type semiconductor layer 131 is on the illumination layer 132. The three illumination regions 11, 12, 13 sharing the n-type semiconductor layer 210 results in formation of a co-electrode. Therefore, the first illumination region 11, the second illumination region 12, and the third illumination region 13 can be used in a parallel circuit or a part of a parallel circuit.

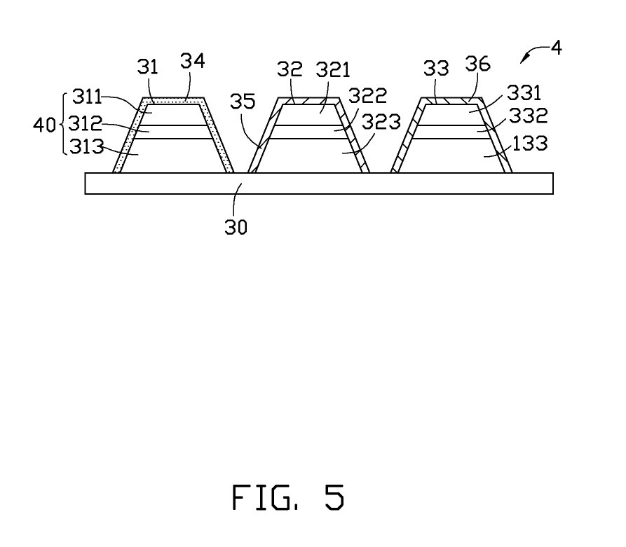

Referring to FIG. 5, a light emitting diode 4 of a fourth embodiment of the disclosure includes a substrate 30, an illumination structure 40, a first fluorescent conversion layer 34, a second fluorescent conversion layer 35, and a third fluorescent conversion layer 36, wherein the illumination structure 40 has a first illumination region 31, a second illumination region 32, and a third illumination region 33. In the fourth embodiment, a space between the first illumination region 31 and the second illumination region 32, or between the second illumination region 32 and the third illumination region 33 is less than 50 μm, wherein the first illumination region 31 has a p-type semiconductor layer 311, an n-type semiconductor layer 313, and an illumination layer 312 between the p-type semiconductor layer 311 and the n-type semiconductor layer 313, the second illumination region 32 has a p-type semiconductor layer 321, an n-type semiconductor layer 323 and an illumination layer 322 between the p-type semiconductor layer 321 and the n-type semiconductor layer 323, the third illumination region 33 has a p-type semiconductor layer 331, an n-type semiconductor layer 333 and an illumination layer 332 between the p-type semiconductor layer 331 and the n-type semiconductor layer 333. Furthermore, the fourth embodiment differs from the first embodiment in that the surface of the third illumination region 33 is covered a third fluorescent conversion layer 36 thereon. The illumination layers 112, 122, 132 emit light with the same wavelength, such as ultraviolet. Since the three illumination regions 31, 32, 33 are physically separated from each other and each have its own electrical circuit, the three illumination regions 31, 32, 33 can be used in series circuit, parallel circuit, series-parallel circuit, or independent circuit. Additionally, the areas between the n-type semiconductor layers 313, 323, 333 and the substrate 30 can further comprise undoped semiconductor layers (not shown).

The first fluorescent conversion layer 34 covers the surface of first illumination region 31, wherein the first fluorescent conversion layer 34 can convert light from the first illumination region 31 to another light having a different wavelength. For example, the first fluorescent conversion layer 34 converts ultraviolet emitted from the first illumination region 31 to red light. Similarly, the second fluorescent conversion layer 35 covers the surface of the second illumination region 32 and converts the ultraviolet light emitted from the second illumination region 32 to green light. Similarly, the third fluorescent conversion layer 36 converts the ultraviolet light emitted from the third illumination region 33 to blue light. As a result, the light emitting diode 4 can mix the red light, green light, and blue light to obtain a desired color rendering index (CRI). Furthermore, a photo-detector can be disposed on the substrate 30 (not shown in FIG. 5) to adjust the input current in the light emitting diode 4 to obtain a desired color rendering index (CRI) of the light mixed.

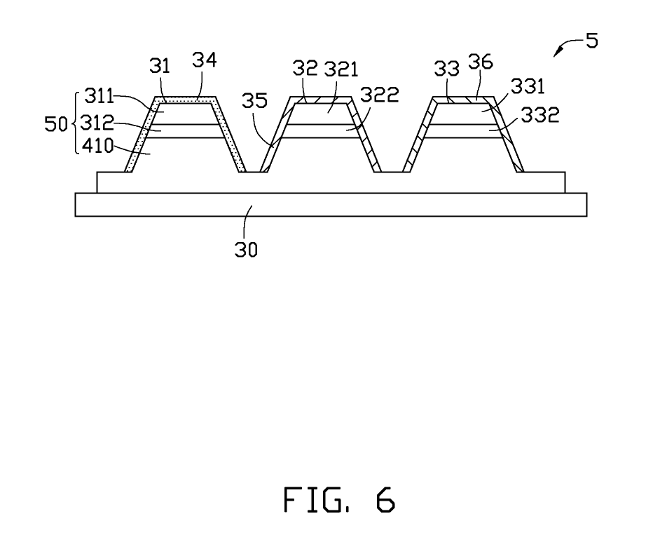

Referring to FIG. 6, a light emitting diode 5 of a fifth embodiment of the disclosure differs from the fourth embodiment in that the first illumination region 31, the second illumination region 32, and the third illumination region 33 share an n-type semiconductor layer 410. The illumination structure 50 has an n-type semiconductor layer 410, p-type semiconductor layers 311, 321, 331, and illumination layers 312, 322, 332, wherein the illumination layers 312, 322, 332 are between the n-type semiconductor layer 410 and the p-type semiconductor layers 311, 321, 331. In other words, the first illumination region 31 has the p-type semiconductor layer 311, a part of the n-type semiconductor layer 410, and the illumination layer 312 therebetween. The second illumination region 32 has the p-type semiconductor layer 321, a part of the n-type semiconductor layer 410, and the illumination layer 322 therebetween., and the third illumination region 33 has the p-type semiconductor layer 331, a part of the n-type semiconductor layer 410, and the illumination layer 332 therebetween. Sharing among the three illumination regions 31, 32, 33 of the n-type semiconductor layer 410 results in formation of a co-electrode, whereby the first illumination region 31, the second illumination region 32, and the third illumination region 33 can be used in a parallel circuit or a part of a parallel circuit.

As disclosed, the fluorescent conversion layer covering the surface of the light emitting diode to obtain light mixed as white light can minimize the capacity of the package, and the disclosure of the light emitting diode has multiple wavelength regions, avoiding the different lifetimes between chips and enhancing efficiency of package. As well, the different wavelengths on the light emitting diode can be mixed better than R, G, B chips, because of distances between the chips.

What is claimed is:

1. A light emitting diode comprising:
a substrate;
an illumination structure including a first illumination region, a second illumination region, and a third illumination region, wherein each of the first illumination region, the second illumination region and the third illumination region has a p-type semiconductor layer, an n-type semiconductor layer and an illumination layer between each of the p-type semiconductor layer and the n-type semiconductor layer;
a first fluorescent conversion layer directly attached on an outer surface of the first illumination region, wherein the first fluorescent conversion layer converts light from the first illumination region to another light having a different wavelength; and
a second fluorescent conversion layer directly attached on an outer surface of the second illumination region, wherein the second fluorescent conversion layer converts light from the second illumination region to another light having a different wavelength.

2. The light emitting diode as claimed in claim 1, wherein the n-type semiconductor layer of the first illumination region, the n-type semiconductor layer of the second illumination region, and the n-type semiconductor layer of the third illumination region are physically separated from each other.

3. The light emitting diode as claimed in claim 1, wherein the n-type semiconductor layer of the first illumination region, the n-type semiconductor layer of the second illumination region, and the n-type semiconductor layer of the third illumination region are integrally formed as a single piece.

4. The light emitting diode as claimed in claim 2, wherein the first illumination region, the second illumination region, and the third illumination region are electrically connected in one of following manners: in series to a DC (direct current) power source, in parallel to a DC power source, in series-parallel to a DC power source, to an AC (alternating current) power source, independently to different DC power sources.

5. The light emitting diode as claimed in claim 3, wherein the first illumination region, the second illumination region, and the third illumination region are used in a series circuit or a part of a series circuit.

6. The light emitting diode as claimed in claim 1, further comprising a photo detector disposed on the substrate.

7. The light emitting diode as claimed in claim 1, wherein the first fluorescent conversion layer converts the light from the first illumination region to red light, and the second fluorescent conversion layer converts the light from the second illumination region to green light.

8. The light emitting diode as claimed in claim 1, wherein the light emitting diode is Group III-V or Group II-VI compound semiconductor.

9. The light emitting diode as claimed in claim 8, wherein the first illumination region, the second illumination region, and the third illumination region generate blue light.

10. The light emitting diode as claimed in claim 8, wherein the first illumination region, the second illumination region, and the third illumination region generate ultraviolent light.

11. The light emitting diode as claimed in claim 10, further comprising a third fluorescent conversion layer disposed on the third illumination region to convert the ultraviolet light from the third illumination region to blue light.

12. The light emitting diode as claimed in claim 1, wherein the first fluorescent conversion layer is made of nitride compounds and the second fluorescent conversion layer is made of nitride oxide compounds.
